(19) United States
(12) Patent Application Publication
(10) Pub. No.: US 2026/0005009 A1
(43) Pub. Date: Jan. 1, 2026

(54) SUBSTRATE PROCESSING METHOD AND SUBSTRATE PROCESSING APPARATUS

(71) Applicant: Tokyo Electron Limited, Tokyo (JP)

(72) Inventors: Yohei SANO, Kumamoto (JP); Tetsuya SADA, Kumamoto (JP)

(21) Appl. No.: 19/246,693

(22) Filed: Jun. 24, 2025

(30) Foreign Application Priority Data
Jun. 27, 2024 (JP) 2024-104196

(51) Int. Cl. H01L 21/02; H01L 21/66

(52) U.S. Cl. CPC H01L 21/02016; H01L 21/02054; H01L 21/02345; H01L 22/12

(57) ABSTRACT

A substrate processing method includes: performing a backside film forming operation that forms a backside film on a back surface of a substrate, wherein the substrate includes a front surface on which a pattern or device structure is formed and the back surface opposite to the front surface, and wherein the backside film is configured to generate stress on the back surface of the substrate upon exposure; and performing an exposing operation that exposes at least a part of the backside film to reduce warpage of the substrate after the backside film forming operation.

### CROSS-REFERENCE TO RELATED APPLICATIONS

This application is based upon and claims the benefit of priority from Japanese Patent Application No. 2024-104196, filed on Jun. 27, 2024, the entire contents of which are incorporated herein by reference.

### BACKGROUND

### Field

The present disclosure relates to a substrate processing method and a substrate processing apparatus.

### Description of the Related Art

Japanese Unexamined Patent Application Publication No. 2021-103022 discloses a substrate processing apparatus that includes a correction member contacting partially the upper surface of a substrate supported by a support member to correct warpage of the substrate. International Publication No. WO 2019/176522 discloses a warpage correction method in which the back surface of a substrate is roughened to form grooves and thereby correct warpage of the substrate.

### SUMMARY

Disclosed herein is a substrate processing method. The substrate processing method may include: performing a backside film forming operation that forms a backside film on a back surface of a substrate, wherein the substrate includes a front surface on which a pattern or device structure is formed and the back surface opposite to the front surface, and wherein the backside film is configured to generate stress on the back surface of the substrate upon exposure; and performing an exposing operation that exposes at least a part of the backside film to reduce warpage of the substrate after the backside film forming operation.

Additionally, a substrate processing apparatus is disclosed herein. The substrate processing apparatus may include: a film forming module configured to form a backside film on a back surface of a substrate, wherein the substrate includes a front surface on which a pattern or device structure is formed and the back surface opposite to the front surface, and wherein the backside film is configured to generate stress on the back surface of the substrate upon exposure; and an exposing module configured to expose at least a part of the backside film to reduce warpage of the substrate after forming the backside film.

### BRIEF DESCRIPTION OF THE DRAWINGS

FIG. 1 is a schematic plan view illustrating an example of a wafer processing system.

FIG. 2 is a schematic side view illustrating an example of a substrate processing apparatus.

FIG. 3 is a schematic side view illustrating an example of a measurement unit.

FIG. 4 is a schematic diagram illustrating an example of a liquid processing unit.

FIG. 5A and FIG. 5B are schematic diagrams illustrating an example of a heat processing unit.

FIG. 6 is a schematic diagram illustrating an example of an reserving unit.

FIG. 7 is a diagram illustrating an example of stress generated by exposure.

FIG. 8 is an example of measurement results of height distribution when exposure is applied to the entire backside film.

FIG. 9 is an example of measurement results of height distribution when exposure is applied to part of the backside film.

FIG. 10 is a schematic side view illustrating an example of an exposure unit.

FIG. 11 is a schematic plan view illustrating an example of an exposure unit.

FIG. 12 is a flowchart illustrating an example of a substrate processing method.

FIG. 13 is a schematic diagram illustrating an example of a substrate processing method.

FIG. 14A is a schematic diagram illustrating an example of performing spin exposure.

FIG. 14B, FIG. 14C, and FIG. 14D are schematic diagrams illustrating shapes of regions to be exposed.

FIG. 15A is a schematic diagram illustrating an example of performing scan exposure.

FIG. 15B and FIG. 15C are schematic diagrams illustrating shapes of regions to be exposed.

FIG. 16A is a schematic diagram illustrating an example of combining spin exposure and scan exposure.

FIG. 16B, FIG. 16C, and FIG. 16D are schematic diagrams illustrating shapes of regions to be exposed.

FIG. 17A is a graph illustrating an example of a relationship between exposure area and height distribution.

FIG. 17B and FIG. 17C are schematic diagrams representing exposed regions.

FIG. 18A is a schematic diagram illustrating an example of a method for adjusting exposure area.

FIG. 18B, FIG. 18C, and FIG. 18D are schematic diagrams illustrating degrees of density of regions to be exposed.

FIG. 19 is a graph illustrating an example of a relationship between the thickness of a film formed on a back surface and warpage amount.

### DETAILED DESCRIPTION

In the following description, with reference to the drawings, the same reference numbers are assigned to the same components or to similar components having the same function, and overlapping description is omitted. Some drawings illustrate an orthogonal coordinate system defined by X-axis, Y-axis, and Z-axis. In following examples, the X-axis and Y-axis correspond to horizontal directions, and the Z-axis corresponds to a vertical direction. A direction of the arrow indicating the Z-axis represents vertically upward.

### [Wafer Processing System]

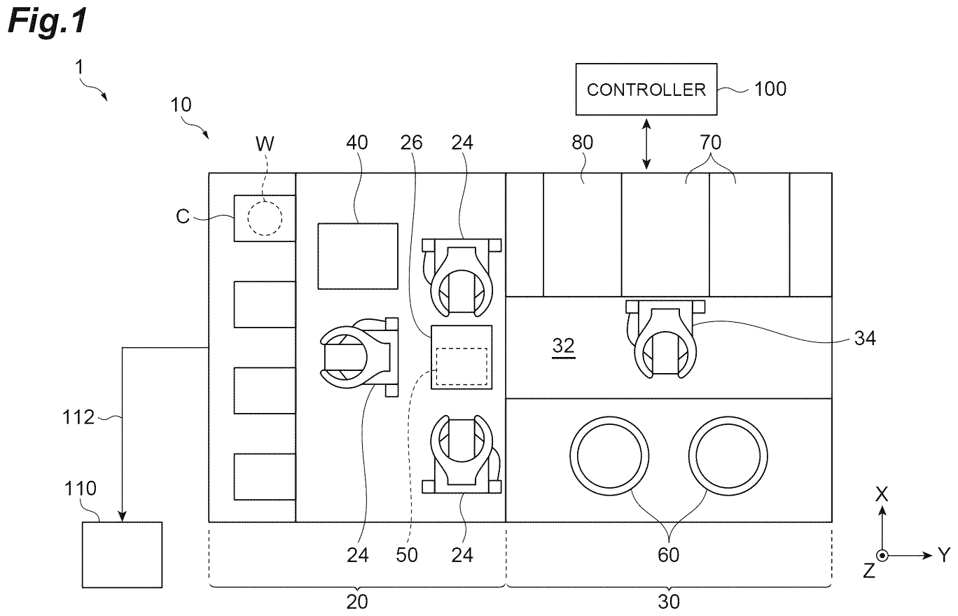

First, the configuration of a substrate processing system according to one example is described. FIG. 1 schematically illustrates a wafer processing system 1 in plan view. The wafer processing system 1 (substrate processing system) may be a system that, after performing warp-reduction processing on a wafer W (substrate), executes a bonding process of two wafers W. The wafer W may be a circular semiconductor wafer. Each wafer W has a pair of opposing main surfaces. One of the main surfaces may already have a pattern or a device structure formed thereon prior to processing by the substrate processing system 1. In this disclosure, a “pattern” means a relief pattern, and a “device structure” means one or more layer constituting one or more semiconductor device.

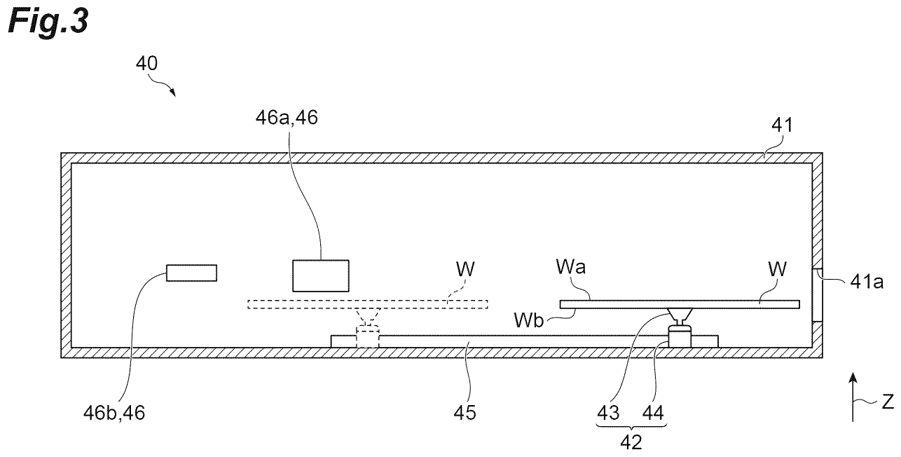

In this disclosure, among the pair of main surfaces of the wafer W, one main surface on which the pattern or the device structure is formed is referred to as “front surface Wa”, and the other main surface is referred to as “back surface Wb” (see, e.g., FIG. 3). The wafer W processed by the substrate processing system 1 has the front surface Wa on which the pattern or the device structure is formed and the back surface Wb opposite to the front surface Wa. Below, a example where the device structure is formed on the front surface Wa is described.

The substrate processing system 1 may include a substrate processing apparatus 10, a transport apparatus 112, and a substrate processing apparatus 110. The substrate processing apparatus 10 is an apparatus configured to accept a wafer W with a device structure formed on the front surface Wa and to perform warp-reduction processing on that wafer W. Details of the substrate processing apparatus 10 are described below. The transport apparatus 112 is configured to transport the wafer W processed by the substrate processing apparatus 10 to the substrate processing apparatus 110.

The substrate processing apparatus 110 is an apparatus configured to execute a bonding process between the wafer W processed by the substrate processing apparatus 10 and another wafer W. The substrate processing apparatus 110 may be configured to perform bonding to the other wafer W with holding the back surface Wb of the processed wafer W by the substrate processing apparatus 10. The other wafer W may likewise be one processed by the substrate processing apparatus 10. The substrate processing apparatus 110 may bond a device structure on the front surface Wa of one wafer W to a device structure on the front surface Wa of the other wafer W.

### [Substrate Processing Apparatus]

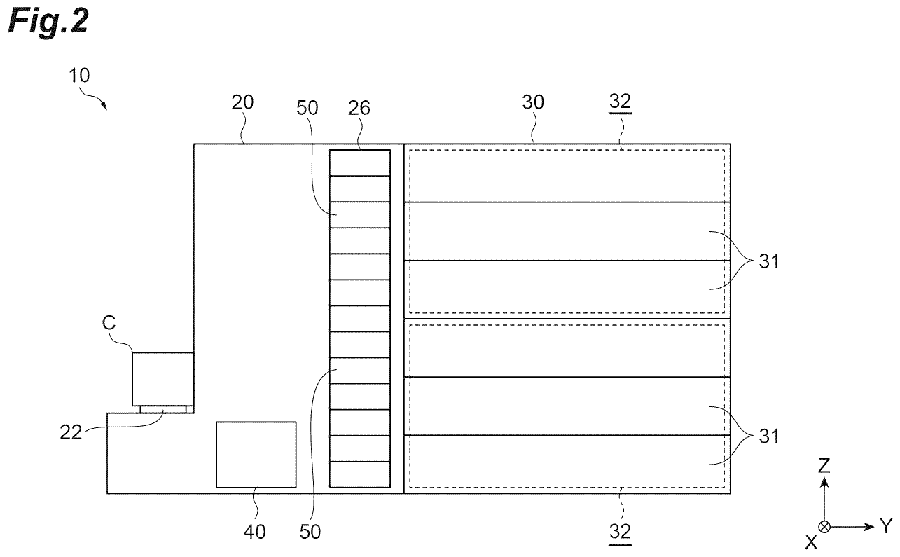

FIG. 2 schematically illustrates a side-view (front view) of the substrate processing apparatus 10. As shown in FIGS. 1 and 2, the substrate processing apparatus 10 may include a loading block 20, a processing block 30, and a controller 100.

The loading block 20 is a block configured to carry the substrate W into and out of the substrate processing apparatus 10. The loading block 20 may include placement tables 22. Each placement table 22 is configured to support a cassette C, which accommodates wafers W. Within cassette C, wafers W may be stored with the front surface Wa facing upward. The loading block 20 may further include transport units 24, a shelf unit 26, a measurement unit 40, and two or more reserving units 50.

The transport units 24 transport wafers W between the cassette C and positions where they can be handed over to the processing block 30. One transport unit 24 is configured to carry a wafer W between the cassette C and the measurement unit 40, and another transport unit 24 is configured to carry a wafer W between the measurement unit 40 and the shelf unit 26 (or reserving unit 50). Each transport unit 24 may include drive mechanisms for X-direction, Y-direction, vertical direction, and θ-direction about a vertical axis as needed. Each transport unit 24 may include drive mechanisms for all of X-direction, Y-direction, vertical direction, and θ-direction.

The shelf unit 26 is partitioned into multiple cells arranged vertically. The shelf unit 26 is located at a position accessible by a transport unit 34 of the processing block 30. The measurement unit 40 is a unit configured to obtain information for measuring the warpage amount of a wafer W. An example of the measurement unit 40 is described later.

Each of the two or more reserving units 50 is a unit configured to reverse the wafer W. Some reserving units 50 are configured to reverse the wafer W so that the back surface Wb faces upward. Other reserving units 50 are configured to reverse the wafer W so that the front surface Wa faces upward. The reserving units 50 may be provided in the shelf unit 26. An example of the reserving units 50 is described later.

The processing block 30 is connected to the loading block 20. The processing block 30 may receive, from the loading block 20, a wafer W before processing by the processing block 30 in a state with the back surface Wb facing upward. The processing block 30 may return, to the loading block 20, a wafer W after processing by processing block 30 in a state with the back surface Wb facing upward. The processing block 30 includes one or more transport units 34, one or more liquid processing units 60, one or more heat processing units 70, and one or more exposure units 80.

As shown in FIG. 2, the processing block 30 may be divided into multiple layers 31 arranged vertically. In each layer 31, one or more of the liquid processing unit 60, the heat processing unit 70, and the exposure unit 80 may be arranged. Each layer 31 is divided into a first area where one or more processing units are arranged, a transport area 32 in where the transport unit 34 transport a wafer W, and a second area where one or more processing units are arranged. In the X-axis direction, the first area, the transport area 32, and the second area are arranged in that order.

Each transport unit 34 may have a transfer arm movable in X, Y, vertical, and θ directions. The transport unit 34 moves within the transport area 32 and is able to transport a wafer W to one or more of the liquid processing unit 60, the heat processing unit 70, and the exposure unit 80. The processing block 30 may include transport units 34 arranged at different heights. Each of the transport units 34 may be configured to transport a wafer W in a corresponding area of the transport areas 32 located at different height positions. In the processing block 30, one transport unit 34 may be provided for every two or more layers 31, or one transport unit 34 may be provided for each layer 31.

The liquid processing unit 60 is a unit configured to form a processing-liquid film on the back surface Wb. The heat processing unit 70 is a unit configured to apply heat processing to the processing-liquid film, thereby forming a film on the back surface Wb. Below, the film formed on the back surface Wb by the liquid processing unit 60 and the heat processing unit 70 is referred to as the “backside film.” The exposure unit 80 is a unit configured to expose at least a part of the backside film. The heat processing unit 70 is also configured to apply heat processing to the backside film after exposure. Examples of the units 60, 70, and 80 are described later.

The controller 100 (control section) may be a computer having a program storage. The program storage is configured to store programs that control the processing of wafers W by the substrate processing apparatus 10. The program storage is also configured to store programs that control operations of the various processing units and transport units to cause the substrate processing apparatus 10 to execute a wafer-processing method (for example, a substrate processing method described below). The programs may be recorded in a computer-readable medium H and installed into the controller 100 from that medium H.

The above configuration of the substrate processing apparatus 10 is an example. The arrangement and the number of processing units or transport units may be changed as appropriate. Processing units other than the measurement unit 40, liquid processing unit 60, heat processing unit 70, and exposure unit 80 may be provided in either the loading block 20 or the processing block 30. For example, one or more processing units selected from a unit performing hydrophobization processing, a unit performing cleaning processing, a unit performing cooling, a unit performing relay between two transport units, and a unit performing alignment of the wafer W may be provided in the substrate processing apparatus 10.

### (Measurement Unit)

FIG. 3 schematically illustrates the measurement unit 40 as seen from the side. The measurement unit 40 is configured to generate image information for measuring a warpage amount of the wafer W. The measurement unit 40 may be configured to support the wafer W with the front surface Wa facing upward and the back surface Wb facing downward while executing measurement processing to generate the image information. The measurement unit 40 may include a housing 41, a rotation holder 42, a driver 45, and an imaging section 46.

The housing 41 houses the rotation holder 42, the driver 45, and the imaging section 46. One side wall of the housing 41 is formed with an inlet/outlet port 41a for carrying the wafer W in and out of the housing 41.

The rotation holder 42 is configured to hold and rotate the wafer W. The rotation holder 42 includes a holding stage 43 and a rotation driver 44. The holding stage 43 is, for example, a suction chuck configured to hold the wafer W substantially horizontally by vacuum adsorption. The holding stage 43 is configured to support back side of the wafer W. Supporting the back side of the wafer W means that supporting the wafer W in contact with either the back surface Wb itself or in contact with a film formed on the back surface Wb.

The rotation driver 44 includes, for example, an electric motor as a power source and is configured to rotationally drive the holding stage 43. When the holding stage 43 is driven to rotate, the wafer W supported by the holding stage 43 rotates. The holding stage 43 may support the wafer W so that the rotation axis of the holding stage 43 aligns with the center of the wafer W. The rotation driver 44 may include an encoder for detecting a rotational position (angle) about the center axis of the holding stage 43.

The driver 45 is, for example, a linear actuator configured to move the rotation holder 42 in a horizontal direction. The driver 45 may reciprocate the rotation holder 42 between a first position near the inlet/outlet port 41a and a second position away from the inlet/outlet port 41a and closer to the imaging section 46.

The imaging section 46 is able to image the edge of the wafer W. The imaging section 46 includes an illumination module 46a and a camera 46b. The illumination module 46a is configured to emit light at the timing when the camera 46b captures an image. The camera 46b is configured to image an edge surface of the wafer W through optics in the illumination module 46a. From the image captured of the edge surface of the wafer W, it is possible to detect information indicating the state of warpage at the peripheral portion of the wafer W.

### (Liquid Processing Unit)

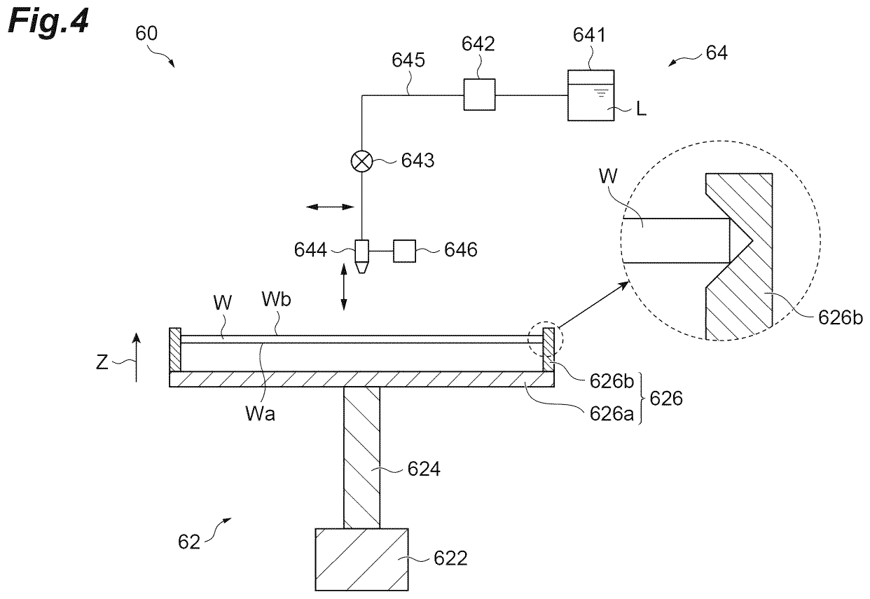

FIG. 4 schematically illustrates the liquid processing unit 60. The liquid processing unit 60 is configured to perform liquid processing using a processing liquid (hereinafter referred to as “processing liquid L”) to form the backside film. The liquid processing unit 60 is configured to perform a liquid processing by using the processing liquid L. The liquid processing unit 60 is configured to perform the liquid processing while supporting the wafer W with the back surface Wb facing upward and the front surface Wa facing downward. The liquid processing unit 60 includes a rotation holder 62 and a liquid supply section 64.

The rotation holder 62 is configured to support the wafer W so that the back surface Wb faces upward and rotate the wafer W. The rotation holder 62 includes a rotation driver 622, a shaft 624, and a holding section 626. The rotation driver 622 includes, for example, an electric motor as a power source and is configured to rotate the shaft 624 about a vertical axis.

The holding section 626 (supporter) is provided at the upper end of the shaft 624. The holding section 626 is configured to hold the wafer W so as not to contact any device structure on the front surface Wa. The holding section 626 includes a first portion 626a and a second portion 626b. The first portion 626a is formed as a circular plate and connects the shaft 624 to the second portion 626b. The second portion 626b is provided on the outer periphery of the upper surface of the first portion 626a and is configured to hold a part of the outer edge portion of the wafer W along a circumference. As shown in the enlarged view of FIG. 4, the second portion 626b has a recess into which the outer edge portion of the wafer W fits. At least a part of the second portion 626b is horizontally movable relative to the first portion 626a, enabling switching between a state in which the wafer W is held and a state in which holding the wafer W is released.

The liquid supply section 64 is configured to supply the processing liquid L to the back surface Wb of the wafer W by discharging the processing liquid L toward the back surface Wb. The processing liquid L is a solution configured to generate stress when the backside film formed by the processing liquid L is exposed. The generation of stress due to the exposure of the backside film will be described later. The liquid supply section 64 includes a liquid source 641, a pump 642, a valve 643, a nozzle 644, piping 645, and a driver 646.

The liquid source 641 functions as a supply source of the processing liquid L. The pump 642 is configured to draw the processing liquid L from the liquid source 641 and deliver it to the nozzle 644 via the piping 645 and the valve 643. The valve 643 is configured to open and close a flow path in the piping 645. The nozzle 644 is arranged above the wafer W supported by the holding section 626 so that its outlet faces the back surface Wb. The nozzle 644 is configured to discharge the processing liquid L to the back surface Wb of the wafer W.

The piping 645 connects, in order from the upstream side, the liquid source 641, the pump 642, the valve 643, and the nozzle 644. The driver 646 includes, for example, an electric motor as a power source and is configured to move the nozzle 644 in horizontal and vertical directions.

### (Heat Processing Unit)

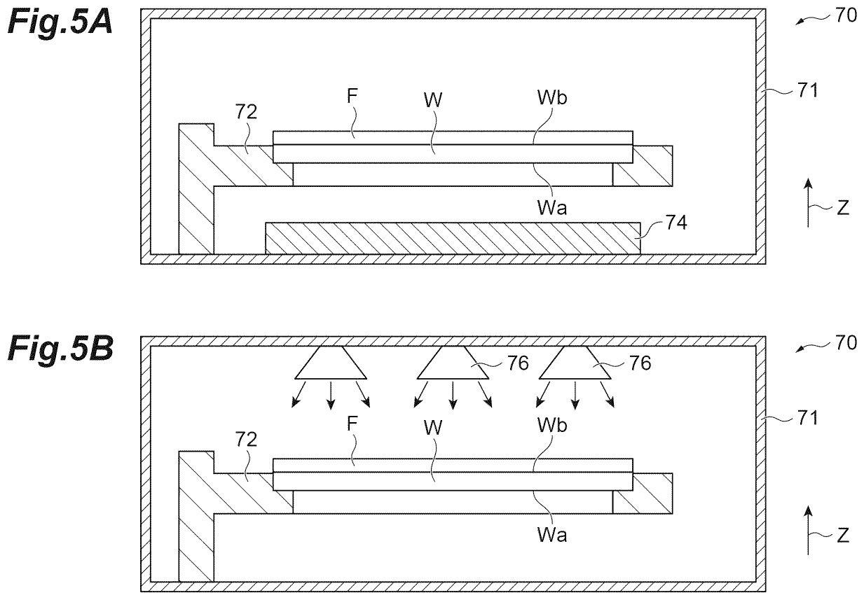

FIG. 5A schematically illustrates a heat processing unit 70. The heat processing unit 70 (heat processing module) shown in FIG. 5A is configured to heat a coating formed on the back surface Wb using a hot plate. The coating formed on the back surface Wb collectively refers to the film of the processing liquid L before deposition and the deposited film obtained by heating the film of the processing liquid L. Hereinafter, for the sake of convenience in explanation, the coating of the processing liquid L formed on the backside Wb will be referred to as “backside film F.” The heat processing unit 70 is configured to support the wafer W with the back surface Wb facing upward and the front surface Wa facing downward while performing heat processing on the backside film F. As shown in FIG. 5A, the heat processing unit 70 includes a housing 71, a support section 72, and a hot plate 74. The housing 71 houses the support section 72 and the hot plate 74, is configured to form a space for heat processing of the backside film F. The support section 72 (supporter) is configured to support the wafer W so as not to contact any device structure on the front surface Wa. For example, the support section 72 is annular and supports an outer peripheral area of the front surface Wa where no device structure is formed, from below. The support section 72 may be connected to an inner wall of the housing 71 via a fixing member.

The hot plate 74 is disposed below the support section 72 at a position where it does not contact the wafer W. The hot plate 74 may be spaced below the support section 72. The hot plate 74 contains a heater such as a resistive heating element. When the temperature of the hot plate 74 increases, heat is transmitted to the backside film F on the back surface Wb.

FIG. 5B schematically illustrate a heat processing unit 70 configured to applies heat to the backside film F by a method different from the heat processing unit 70 shown in FIG. 5A. The heat processing unit 70 in FIG. 5B includes a housing 71, a support section 72, and one or more irradiation sections 76. The irradiation sections 76 are provided in the housing 71 so as to be able to irradiate the backside film F on the back surface Wb of the wafer W with light. Irradiation of light heats the backside film F. Unlike the exposure light used by the exposure unit 80, the light from the irradiation sections 76 may be selected so that substantially no reaction proceeds in the backside film F.

By the liquid processing unit 60 and the heat processing unit 70, the backside film F is formed on the back surface Wb. Both the liquid processing unit 60 and the heat processing unit 70 may form a film forming module configured to form a backside film which is configured to generate stress on the back surface Wb of the substrate W upon exposure. In this disclosure, the stress caused upon exposure includes the stress generated by performing heat processing after irradiating with exposure light.

### (Reserving Unit)

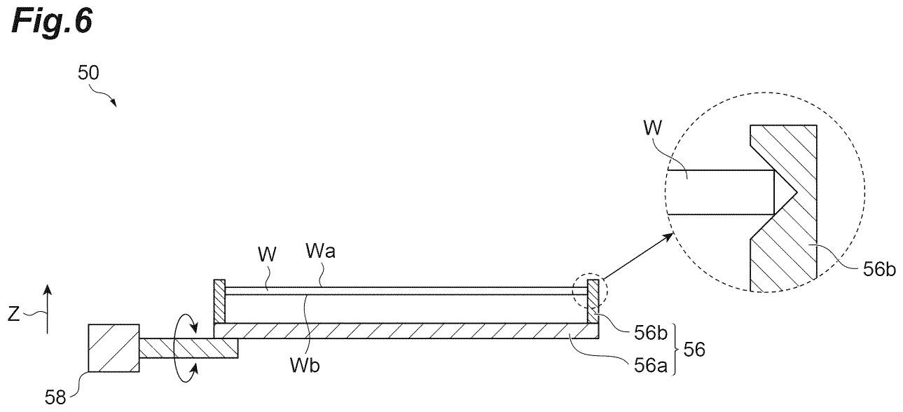

FIG. 6 schematically illustrates an reserving unit 50 as seen from the side. The reserving unit 50 includes, for example, a holding section 56 and a driver 58. The holding section 56 is a section configured to hold the wafer W. The holding section 56 is configured to hold the wafer W so that either the front surface Wa or the back surface Wb faces upward. The holding section 56 may be configured similarly to the holding section 626 of the liquid processing unit 60 shown in FIG. 4. The holding section 56 may include a part 56a corresponding to the first portion 626a of the holding section 626 and a part 56b corresponding to the second portion 626b of the holding section 626.

The driver 58 is connected to the holding section 56 and configured to rotate the holding section 56 about a horizontal axis. The driver 58 may be an actuator including a power source such as an electric motor. The driver 58 may rotate the holding section 56 by 180° about the horizontal axis so that the top and bottom of the holding section 56 are reversed. As the holding section 56 rotates 180° around the horizontal axis, the top and bottom of the wafer W are inverted.

### (Properties of the Backside Film)

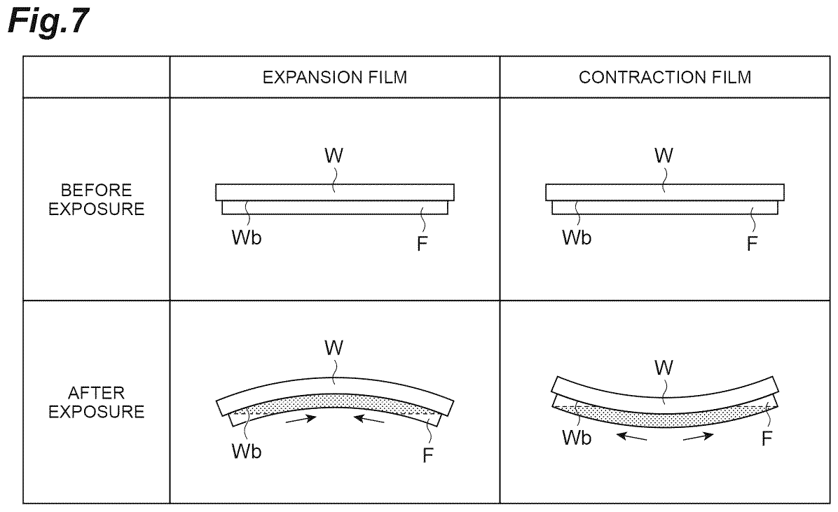

Referring to FIGS. 7 to 9, the stress generated in the backside film F by exposure and its relationship to warpage reduction of the wafer W are explained. FIG. 7 schematically illustrates the relationship between a type of backside film F and both exposure-induced stress and deformation with using a table. The backside film F may be an expansion film whose volume increases by chemical reaction or a contraction film whose volume decreases by chemical reaction. In the schematic diagram of FIG. 7, the back surface Wb faces downward and the backside film F lies beneath the wafer W (bare wafer). The backside film F may a film containing a resin that cross-links upon exposure (a resin-containing film that crosslinks upon exposure).

As shown in FIG. 7, when the backside film F formed on the back surface Wb is an expansion film, stress directed inward is generated when the backside film F expands due to chemical changes caused by exposure. The stress generated in the expansion film is tensile stress. Assuming that there is no warpage in the wafer W before exposure, deformation occurs such that the peripheral portion of the wafer W bends downward. When the backside film F formed on the back surface Wb is a contraction film, stress directed outward is generated when the backside film F shrinks due to chemical changes caused by exposure. The stress generated in the contraction film is compressible stress. Assuming that there is no warpage in the wafer W before exposure, deformation occurs such that the peripheral portion of the wafer W bends upward.

Processing liquid L for forming expansion films may be a solvent containing components that crosslink upon exposure (exposure and heat processing). In one example, the processing liquid L may be a negative resist containing a photosensitive epoxy resin with a viscosity of about 800 cP to 1200 cP. The processing liquid L for forming the expansion film may be a chemical solution containing a photosensitive polyimide resin. When the backside film F is a contraction film, the contraction film may be an oxide film. The contraction film may be a film containing an oxide including silicon (Si), and, in one example, the processing liquid L for forming the contraction film is a chemical solution containing tetraethoxysilane (TEOS). The following description assumes that the backside film F is an expansion film.

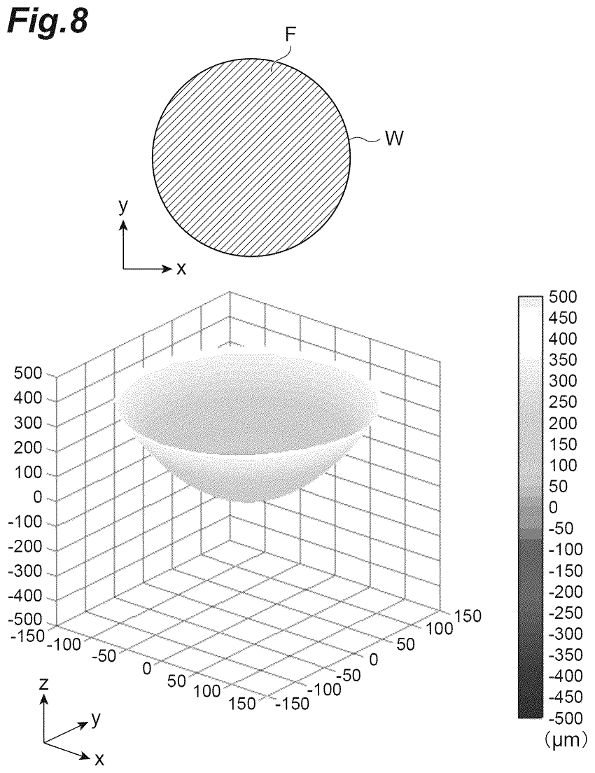

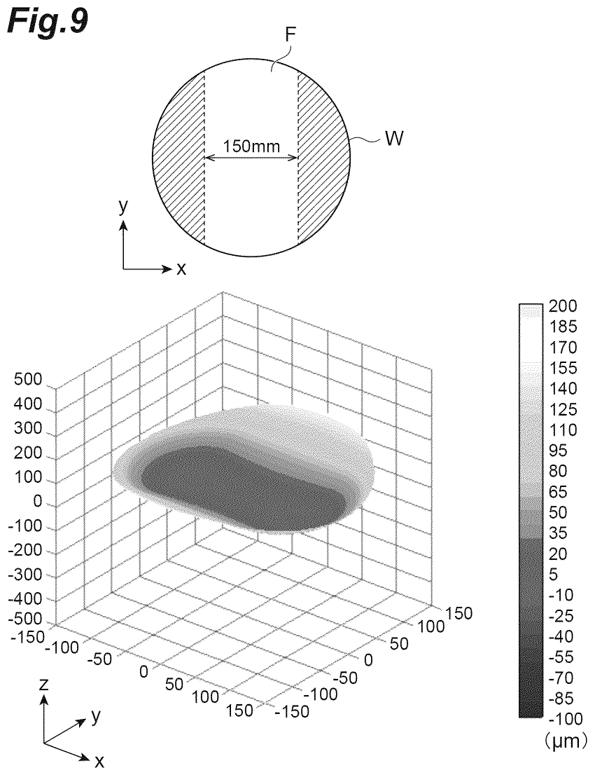

FIGS. 8 and 9 illustrate example results of measuring the height distribution in the main surface of the wafer after both forming the backside film F on back surface Wb and performing exposure on the backside film F. Assuming that the wafer W is flat, positions in the main surface of the wafer W are specified by the coordinates of the mutually orthogonal x-axis and y-axis. The z-axis, which is orthogonal to the x-axis and y-axis, represents a height position of a top surface of the backside film F at each of the positions in the main surface of the wafer W. The height position is measured while the back surface Wb is facing upward.

In the results shown in FIG. 8, the height distribution when exposure light is applied across the entire backside film F is measured. It appears that the wafer's peripheral regions warp upward relative to its center. In the results of FIG. 9, the height distribution when exposure light is applied only to the two end regions of the backside film F in the x-axis direction, leaving the central portion (150 mm range) unexposed, is measured. Focusing on both the end regions in the x-axis direction, stress is generated toward the central part along the y-axis direction. As a result, it appears that both end portions in the y-axis direction are deformed such that they warp upward.

From the above considerations, it is understood that when there was warpage before the backside film F was formed, it is possible to reduce the warpage by forming the backside film F on the back surface Wb and then exposing at least a part of the back surface Wb. Which region of the backside film F the exposure light is irradiated to in order to reduce warpage is determined, for example, through trials or simulations conducted before production by the wafer processing system 1.

### (Exposure Unit)

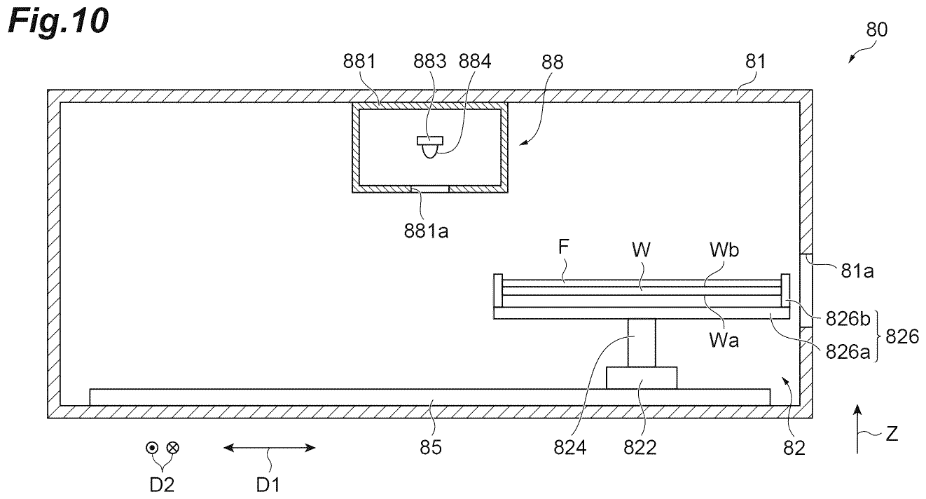

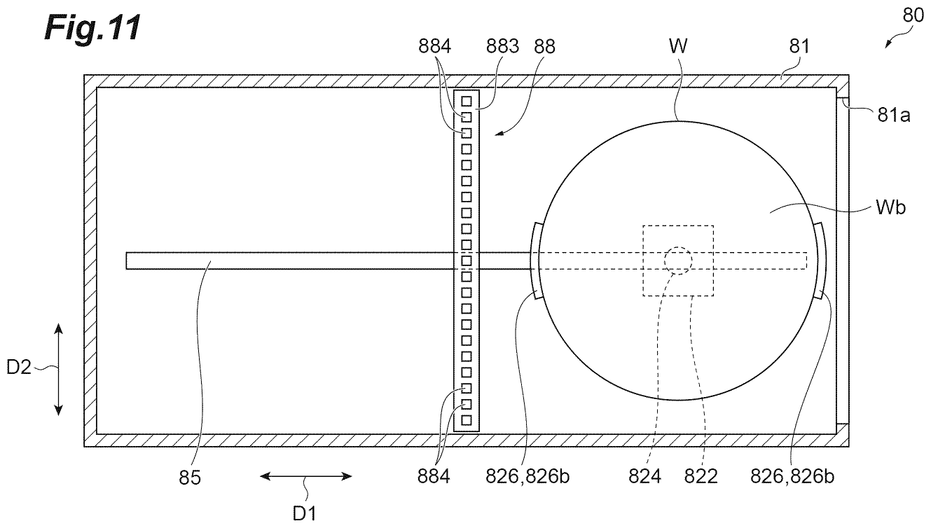

FIG. 10 illustrates a schematic side view of an exposure unit 80, and FIG. 11 illustrates a schematic plan view of an exposure unit 80. The exposure unit 80 (exposing module) is configured to expose at least a part of the backside film F after its formation on the back surface Wb so as to reduce warpage of the wafer W. The exposure unit 80 may be configured to reduce warpage of the wafer W with exposing at least a part of the backside film F after forming the backside film F. The exposure unit 80 is, for example, configured to adjust the exposure region on the backside film F in accordance with instructions from the controller 100.

The exposure unit 80 may support the wafer W with the back surface Wb facing upward and the front surface Wa facing downward while irradiating exposure light onto the backside film F. As shown in FIGS. 10 and 11, the exposure unit 80 includes a housing 81, a rotation holder 82, a driver 85, and an irradiation section 88.

The housing 81 is configure to house the rotation holder 82, the driver 85, and the irradiation section 88. One side wall of the housing 81 is provided with an inlet/outlet port 81a for carrying the wafer W into the housing 81 and carrying the wafer W out of the housing 81.

The rotation holder 82 is configured to hold the wafer W so that the back surface Wb faces upward and to rotate the wafer W. The rotation holder 82 includes a rotation driver 822, a shaft 824, and a holding section 826. The rotation driver 822 includes a power source such as an electric motor, is configured to rotate the shaft 824 about a vertical axis. The holding section 826 (supporter) is provided at the upper end of the shaft 824 and is configured to hold the wafer W so as not to contact the device structure on the front surface Wa.

The holding section 826 may be configured similarly to the holding section 626 of the rotation holder 62 in the liquid processing unit 60. The holding section 826 includes a first portion 826a and a second portion 826b. The first portion 826a is formed as a circular plate and connects the shaft 824 and second portion 826b. The second portion 826b is provided on the outer periphery of the upper surface of the first portion 826a and is configured to hold a part of the outer edge portion of the wafer W along a circumference. The second portion 826b may be similarly configured to the second portion 626b of the liquid processing unit 60. At least a part of second portion 826b is horizontally movable relative to the first portion 826a, enabling switching between a state in which the wafer W is held and a state in which holding the wafer W is released.

The driver 85 is, for example, a linear actuator configured to move the rotation holder 82 in a horizontal direction. The direction in which the rotation holder 82 moves by the driver 85 is defined as “direction D1”, and the horizontal direction orthogonal to the direction D1 is defined as “direction D2”. The driver 85 is configured to reciprocate the rotation holder 82 between a first position close to the inlet/outlet 81a and a second position away from the inlet/outlet 81a along the direction D1 (second direction).

The irradiation section 88 is configured to irradiate exposure light onto at least a part of the backside film F of the wafer W held by the rotation holder 82. The irradiation section 88 is located between the first position and the second position in the direction D1, allowing exposure light to be applied as the wafer W moves in the direction D1. The irradiation section 88 includes a case 881, a support substrate 883, and LEDs 884.

The case 881 is, for example, attached to the top wall of the housing 81 and is configured to house the support substrate 883 and the LEDs 884. An opening 881a for emitting exposure light is formed in the bottom of the case 881. A shutter may be provided to open/close opening 881a. Above the opening 881a, the support substrate 883 is provided. The support substrate 883 is formed to extend along a direction crossing the direction D1. The support substrate 883 may extends along the direction D2. The support substrate 883 may be a circuit board. The support substrate 883 is, for example, fixed at some location on the case 881.

Each of the LEDs 884 is a light source configured to emit exposure light. The LEDs 884 are mounted on the underside of the support substrate 883 and supported by the support substrate 883. The LEDs 884 (a plurality of light sources) are arranged along the direction D2 (first direction). The LEDs 884 may be arranged at equal intervals in the direction D2. The number of LEDs 884 may range from 50 to 150. In the example shown in FIG. 11, the LEDs 884 are arranged in a single row, but they may also be arranged in two or more rows in a matrix.

Each LED 884 is configured to emit, as exposure light, radiation in a frequency band that induces the chemical reaction (crosslinking) in backside film F. For example, each LED 884 is configured to emit ultraviolet light. Each LED 884 may be configured to emit exposure light vertically downward. The LEDs 884 may be individually controllable for turning on (lighting) and off (extinguishing). The driver 85 is configured to move the rotation holder 82 in the direction D1 so that, in plan view, the wafer W crosses the LEDs 884. While the wafer W moves in the direction D1 by the driver 85, exposure light from at least some of the LEDs 884 may be irradiated onto the backside film F.

### [Substrate Processing Method]

An example of a substrate processing method executed using the substrate processing apparatus 10 is described below. This substrate processing method includes at least a backside film forming operation and an exposing operation. The backside film forming operation is an operation of forming the backside film F that generates stress upon exposure. The exposing operation is an operation of exposing at least a part of the backside film F to reduce warpage of the wafer W after forming the backside film F. The backside film forming operation and the exposing operation may be performed within the substrate processing apparatus 10.

The backside film forming operation may include a liquid processing operation and a first heating operation. The liquid processing operation is an operation of supplying processing liquid L to the back surface Wb to form a film of processing liquid L. The first heating operation is an operation of applying heat processing on that film of processing liquid L to convert it into a coating. In the substrate processing method, a second heating operation may be performed after the exposing operation. The second heating operation is an operation of applying heat processing on the backside film F after exposure.

The substrate processing method may include a loading operation, an unloading operation, a first reversing operation, and a second reversing operation. The loading operation is an operation of carrying the wafer W without the backside film F into the substrate processing apparatus 10. The unloading operation is an operation of carrying the wafer W with the backside film F having been exposed out of the substrate processing apparatus 10. The first reversing operation is an operation of reversing the wafer W without the backside film F so that the back surface Wb faces upward. The second reversing operation is an operation of reserving the wafer W with the backside film F at least a part of which has been exposed so that the front surface Wa faces upward.

The loading operation, the unloading operation, the first reversing operation, and the second reversing operation may be performed in the loading block 20. The backside film forming operation, the exposing operation, and the second heating operation may be performed in the processing block 30. In each of the backside film forming operation, the exposing operation, and the second heating operation, the wafer W is supported with the back surface Wb facing upward so as not to contact any region on which a pattern or a device structure is formed in the front surface Wa.

The substrate processing method may further include a first measuring operation, a condition adjustment operation, and a second measuring operation. The first measuring operation is an operation of measuring a warpage amount of the wafer W prior to the backside film forming operation. In the measuring operation, the warpage amount may be defined as a difference between the maximum and minimum values among the measured height data of the edge surface of the wafer W (or a difference between the highest and lowest measured heights). The condition adjustment operation is an operation of adjusting a processing condition of at least one of the backside film forming operation and the exposing operation in accordance with the measured warpage amount. For example, in the condition adjustment operation, the processing condition in the exposing operation may be adjusted for each individual wafer W. The second measuring operation is an operation of measuring the warpage amount of the wafer W after exposure of at least part of the backside film F and subsequent heat processing.

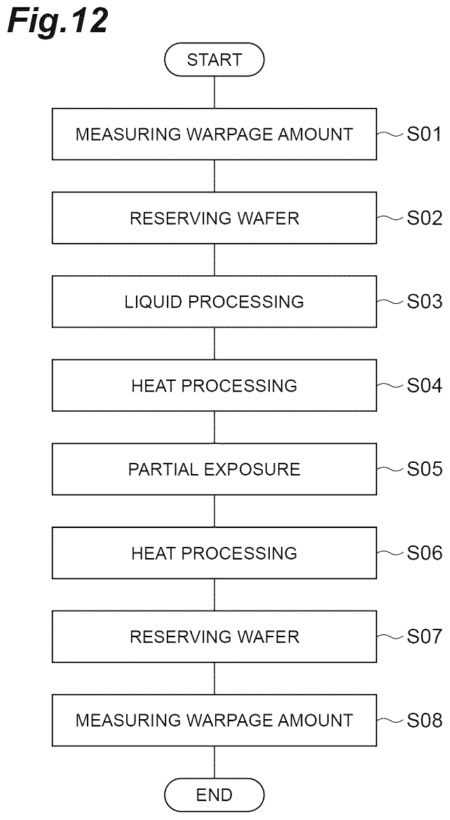

FIG. 12 illustrates an example process flow for the substrate processing method. In this process flow, an exposure target range in the exposing operation is predetermined. The exposure target range represents the maximum region of the backside film F to be irradiated with exposure light. Depending on the processing conditions of the exposing operation, exposure light may be applied across the entire exposure target range. Depending on the processing conditions of the exposing operation, exposure light may be applied to a part of the entire exposure target range. Exposure light is not necessarily applied to the entire exposure target range.

In the substrate processing apparatus 10, multiple wafers W are processed in lots, each lot containing wafers of the same type. Consequently, before carrying into the substrate processing apparatus 10, the wafers within the same lot exhibit similar warpage tendencies. The degree of warpage may be different among individual wafers within the same lot. In the process flow, to reduce differences in warpage amount among the wafers, the processing condition in the exposing operation may be set individually for each wafer W.

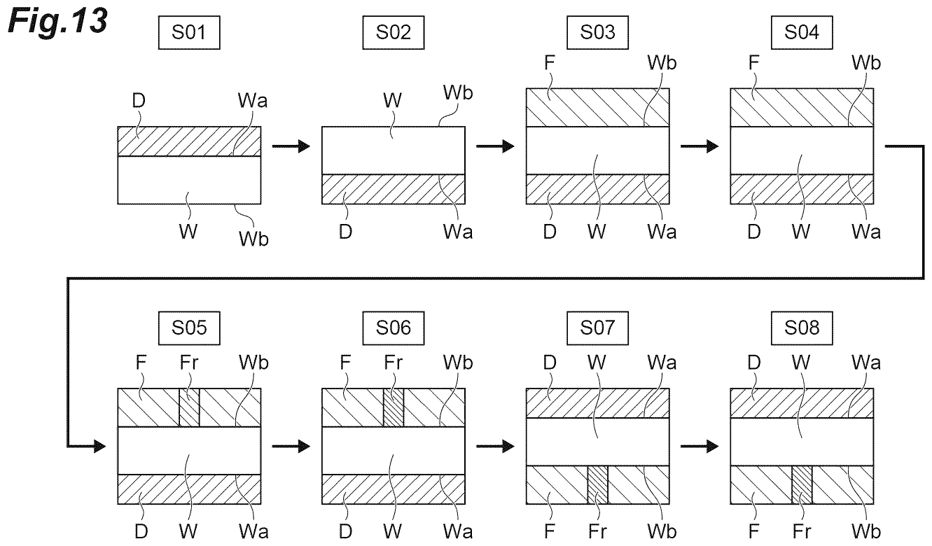

The process flow of FIG. 12 describes a sequence of operations performed for a single wafer W. FIG. 13 schematically illustrates a state of the wafer W at each operation. In this flow, step S01 is executed with the wafer W housed in a cassette C on placement table 22. In step S01, for example, the controller 100 controls transport unit 24 to carry the wafer W from the cassette C to the measurement unit 40. The controller 100 then acquires, from the measurement unit 40, image information obtained by imaging the edge surface of the wafer W.

Next, the controller 100 calculates the warpage amount, indicating the degree of warpage in the edge surface of the wafer W, from the image information obtained by the measurement unit 40. In one example, the controller 100 comparing the image obtained from the measurement unit 40 with a reference image of an edge surface of a reference wafer without warpage. Then the controller 100 calculates a height position of the top in the edge surface of the wafer W at each position (angle) in a circumferential direction around the center of the wafer W. The controller 100 then calculates a difference between the maximum and minimum of these height positions and defines that difference as the warpage amount. Part of step S01 may correspond to the first measuring operation. In FIG. 13, the device structure formed on the front surface Wa is denoted by “D,” and step S01 is performed with the front surface Wa facing upward.

Next, step S02 is executed. In step S02, for example, the controller 100 controls the transport unit 24 to carry the wafer W from the measurement unit 40 to the reserving unit 50 (first reserving module) provided in the shelf unit 26. The controller 100 then causes the reserving unit 50 to invert the wafer W so that the front surface Wa faces downward and the back surface Wb faces upward. Part of step S02 may correspond to the first reversing operation. Execution of step S02 transitions the wafer W to a state with the back surface Wb facing upward (see FIG. 13).

Next, step S03 is executed. In step S03, for example, the controller 100 controls the transport unit 34 to carry the wafer W from the reserving unit 50 to the liquid processing unit 60. The controller 100 then causes the liquid processing unit 60 to supply the processing liquid L and form a film of the processing liquid L (the backside film F) on the back surface Wb. As a result of step S03, the backside film F is formed on the back surface Wb facing upward (see FIG. 13).

Next, step S04 is executed. In step S04, for example, the controller 100 controls the transport unit 34 to carry the wafer W from the liquid processing unit 60 to the heat processing unit 70. The controller 100 then causes the heat processing unit 70 to apply heat processing to the wafer W so that the back surface Wb is coated with the backside film F. Part of step S04 may correspond to the first heating operation.

Next, step S05 is executed. In step S05, for example, the controller 100 controls the transport unit 34 to carry the wafer W from the heat processing unit 70 to the exposure unit 80. The controller 100 then causes the exposure unit 80 to irradiate exposure light onto at least a part of the exposure target range of the backside film F. In FIG. 13, a portion of the backside film F that have been exposed are marked “Fr” and depicted with a distinct pattern. Part of step S05 may correspond to the exposing operation.

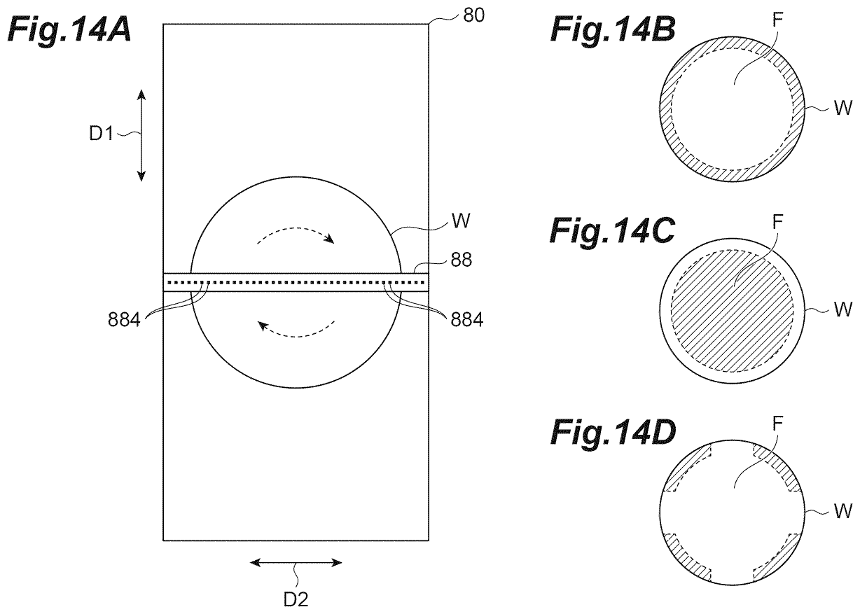

Referring to FIGS. 14A to 14D, 15A to 15C, and 16A to 16D, an example of how to irradiate exposure light in accordance with the predetermined exposure target range is described. In the exposing operation included in step S05, exposure of at least a part of backside film F may be carried out by irradiating exposure light from at least some of LEDs 884 arranged along the direction D2 while moving the wafer W along direction D1. Irradiating exposure light while moving the wafer W along the direction D1 is not limited to irradiating exposure light while continuously moving the wafer W in the direction D1. Irradiating exposure light while moving the wafer W along the direction D1 also includes temporarily stopping the movement in the direction D1 and irradiating exposure light while moving (including rotating) the wafer W in a direction other than direction D1.

As shown in FIG. 14A to 14D, the controller 100 may cause the driver 85 to move the rotation holder 82 (and the wafer W) along the direction D1 until the center of the wafer W reaches the position of the LEDs 884. Then, while rotating the wafer W via the rotation driver 822 of the rotation holder 82, the controller 100 may cause the irradiation section 88 to emit exposure light from at least some of the LEDs 884. After that, with all LEDs 884 turned off by the irradiation section 88, the controller 100 may cause the driver 85 to return the rotation holder 82 (and the wafer W) to its initial position.

Thus, “irradiating exposure light from at least some of the LEDs 884” may include irradiating exposure light during at least a part of a period in which the wafer W is being rotated while stationary in the direction D1. In this disclosure, irradiating exposure light while the wafer W is rotating with the movement in the direction D1 halted is called “spin exposure.” FIGS. 14B, 14C, and 14D illustrate example shapes of regions exposed by spin exposure. The exposed regions are shown with slanted hatching. The slanted hatching may represent the same meaning in other figures. Unlike the examples in FIGS. 14B to 14D, the shape of a region exposed by spin exposure does not need to be point-symmetric with respect to the center of the wafer W, nor does it need to be line-symmetric with respect to an imaginary line passing through the center of the wafer W.

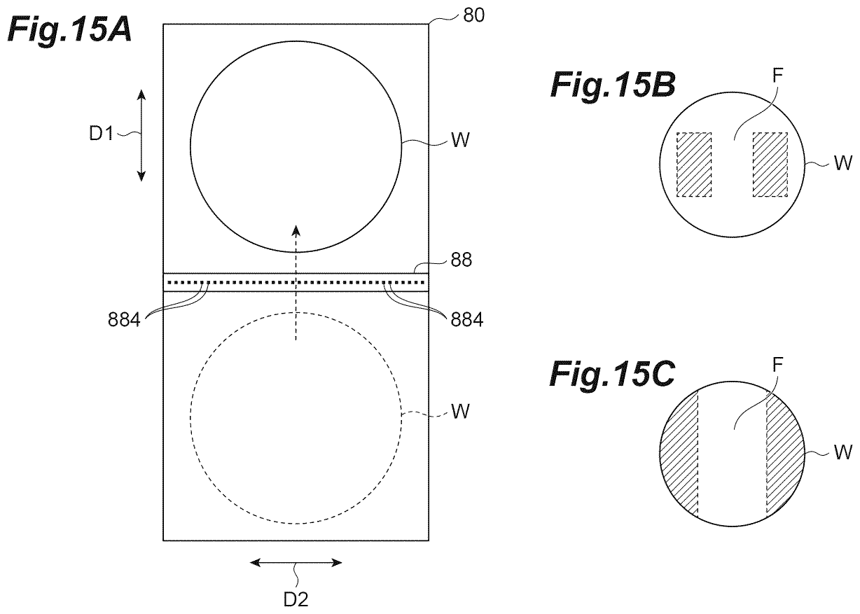

As shown in FIG. 15A to 15C, the controller 100 may cause the driver 85 to move the rotation holder 82 (and the wafer W) along the direction D1 until the wafer W entirely passes beyond the irradiation section 88. The controller 100 may control the irradiation unit 88 to emit exposure light from at least some of the LEDs 884 while moving the wafer W along the direction D1 by the driver 85. After that, with all LEDs 884 turned off by the irradiation section 88, the controller 100 may cause the driver 85 to return the rotation holder 82 (and the wafer W) to its initial position.

Thus, “irradiating exposure light from at least some of the LEDs 884” may include irradiating exposure light during at least a part of the period in which the wafer W is moving along the direction D1. In this disclosure, irradiating exposure light during at least a part of the period while moving the wafer W along the direction D1 is referred to as “scan exposure.” Unlike the examples shown in FIGS. 15B and 15C, the shape of a region exposed by scan exposure does not need to be line-symmetric with respect to an imaginary line passing through the center of the wafer W.

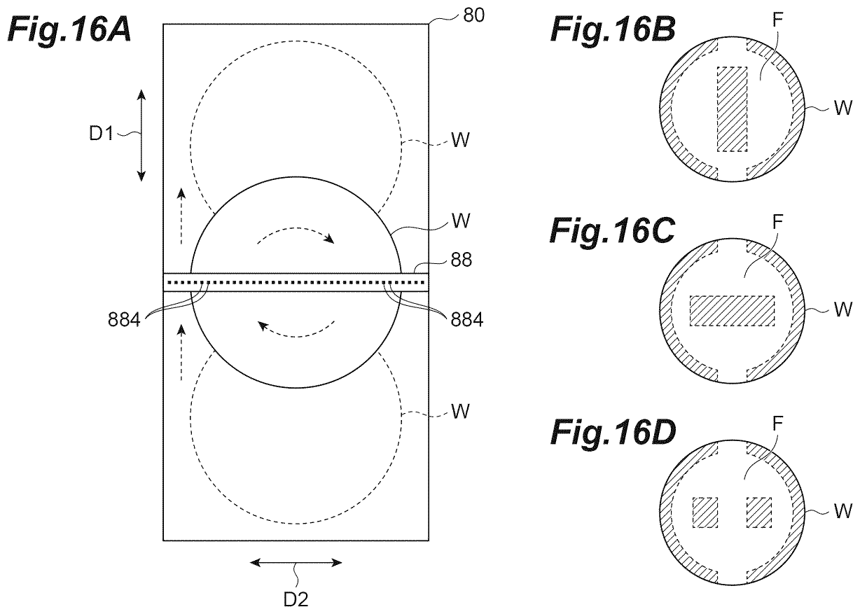

As shown in FIG. 16A to 16D, exposure combining spin exposure and scan exposure may be performed. For example, the controller 100 may sequentially perform the following controls:

(a) Irradiating exposure light from the irradiation section 88 while moving the wafer W by the driver 85 from the initial position until the center of the wafer W reaches the position corresponding to the LEDs 884, so that exposure light is irradiated on half of the region targeted for scan exposure.

(b) Irradiating exposure light from the irradiation section 88 while rotating the wafer W by the rotation driver 822, so that exposure light is irradiated on the entire region targeted for spin exposure.

(c) Irradiating exposure light from the irradiation section 88 while moving the wafer W by the driver 85 until the entire wafer W passes through the irradiation section 88, so that exposure light is irradiated on the remaining half of the region targeted for scan exposure.

After performing the controls of (a), (b), and (c) sequentially, the controller 100 may then control the driver 85 to return the wafer W to its initial position. The controller 100 may perform the following control (c1) instead of the control (c) mentioned above.

(c1) Irradiating exposure light from the irradiation section 88 while moving the wafer W by the driver 85 back to the initial position, so that exposure light is irradiated on the remaining half of the region targeted for scan exposure.

When the controller 100 performs the control (c1) mentioned above, the controller 100 may rotate the wafer W by 180° after performing the control (b) mentioned above. Even when performing scan exposure without performing spin exposure, the controller 100 may perform the control (a) mentioned above, the half rotation of the wafer W, and the control (c1) mentioned above. By performing scan exposure during reciprocating movement instead of unidirectional movement, the size of the exposure unit 80 can be reduced.

FIGS. 16B, 16C, and 16D illustrates example shapes of regions exposed by the combined scan exposure and spin exposure. The controller 100 may control the exposure unit 80 to perform all of either scan exposure or spin exposure first, and then perform all of the other. In the exposure unit 80, by selecting between scan exposure and spin exposure, adjusting the positions and the number of LEDs 884 to be lit, and adjusting the timing of lighting the LEDs 884, it is possible to irradiate exposure light in accordance with the exposure target range.

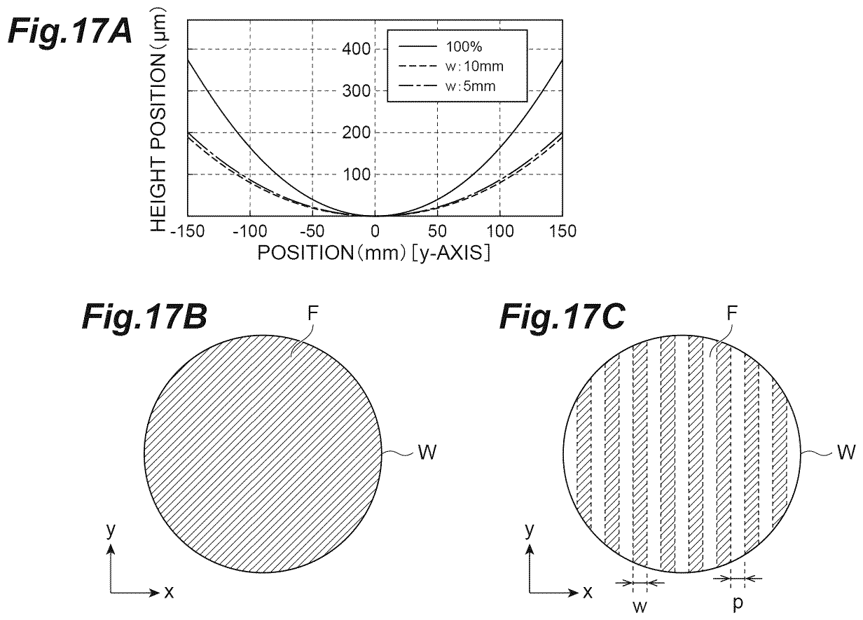

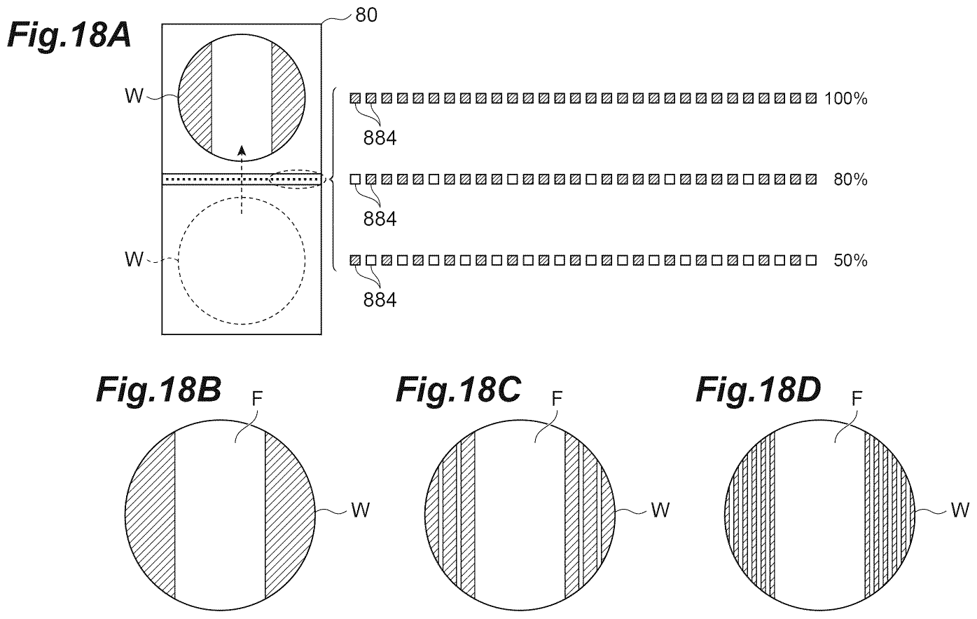

Next, with reference to FIGS. 17A to 17C and 18A to 18D, an example method for adjusting conditions to reduce the degree of warpage within the same lot is described. FIG. 17A illustrates measured height distributions along a wafer diameter when backside film F is formed on a non-warped wafer W and exposure light is applied on the backside film F under different conditions. The horizontal axis is distance along the y-axis from the center of the wafer W; the vertical axis is measured height position. “100%” refers to the measurement results when exposure light is irradiated over the entire area of the backside film F, as shown in FIG. 17B.

“w: 10 mm” and “w: 5 mm” refer to the measurement results when exposure light is irradiated over a partial area of the backside film F that has 50% of the total area. As shown in FIG. 17C, the exposed area (hereinafter referred to as “exposure area”) is adjusted by exposing multiple strip-shaped regions, each region extending in one direction (vertical direction on the page) and arranged at equal intervals in the direction orthogonal to the one direction (horizontal direction on the page). The width of each of the strip-shaped regions is represented by “w,” and the interval between adjacent strip-shaped regions is represented by “p.” In “w: 10 mm,” the width w is set to 10 mm, and the interval p is set to 20 mm. In “w: 5 mm,” the width w is set to 5 mm, and the interval p is set to 5 mm. The radius of the wafer Wis 150 mm. From the graph shown in FIG. 17A, it is apparent that different exposure areas within the exposure target range result in different height positions at the edge surface of the wafer W, and consequently, different amounts of warpage. The controller 100 may adjust the processing condition in the exposing operation so that the exposure area within the exposure target range is larger when the amount of warpage in the wafer W before exposure is relatively large within the same lot. The controller 100 may adjust the processing condition in the exposing operation so that the exposure area within the exposure target range is smaller when the amount of warpage in the wafer W before exposure is relatively small within the same lot.

The controller 100 may compare the warpage amount (measured value) of the wafer W before exposure with a predetermined reference value, and may adjust the exposure area based on the comparison result. The controller 100 may set the exposure area to a first range when the warpage amount of the wafer W before exposure is smaller than the reference value. The controller 100 may set the exposure area to a second range, which is larger than the first range, when the warpage amount of the wafer W before exposure is greater than the reference value. The reference value may be determined by an experiment conducted prior to production, or may be set to the average warpage amount in a previous lot produced under the same conditions. The controller 100 may also adjust the exposure area as the processing condition in the exposing operation by comparing the warpage amount of the wafer W before exposure with each of a plurality of reference values having different values.

The controller 100 may store table information in which the warpage amount of the wafer W before exposure and the exposure area as the processing condition in the exposing operation are associated in advance. In this table information, for example, a range of warpage amounts and a set value of the exposure area are associated with each other. The table information may be determined by an experiment conducted prior to production. The controller 100 may set the exposure area according to the warpage amount (measured value) of the wafer W before exposure by referring to the table information.

When a chemical solution containing a photosensitive epoxy resin and having a viscosity of 800 cP to 1200 cP is used as the processing liquid L, the controller 100 may change the exposure area as follows. The controller 100 may set the exposure area to 70% to 100%, 75% to 100%, 80% to 100%, or 85% to 100% when the warpage amount (measured value) of the wafer W before exposure is greater than a predetermined threshold. The controller 100 may set the exposure area to less than 70%, 30% to 65%, 35% to 60%, or 35% to 55% when the warpage amount (measured value) of the wafer W before exposure is less than the threshold. The threshold may be 250 μm, 260 μm, 270 μm, 280 μm, 290 μm, or 300 μm.

FIG. 18A illustrates an enlarged view of two or more of the LEDs 884 that are capable of irradiating exposure light onto the exposure target range. In the enlarged portion of FIG. 18A, the patterned LEDs 884 indicate those that are lit, and the unpatterned LEDs 884 indicate those that are not lit. The ratio of the number of LEDs 884 that are lit to the number of LEDs 884 that are not lit varies depending on the exposure area, which are 100%, 80%, or 50%.

FIG. 18B schematically illustrates the region exposed when the exposure area is 100%. FIG. 18C illustrates the region exposed when the exposure area is 80%; FIG. 18D illustrates the region exposed when the exposure area is 50%. The arrangement and number of LEDs 884 that are lit in FIG. 18A do not match the arrangement and number of strip-shaped regions in FIG. 18C and FIG. 18D because these are schematic diagrams. As shown in FIGS. 18A to 18D, the exposure area may be adjusted by varying the density of the exposed and unexposed portions within the exposure target range. Instead of adjusting the density, the exposure area may be adjusted by dividing the exposure target range into exposed portion and unexposed portion, and varying the size of the exposed portion. Adjusting the density allows the exposed portions to be distributed within the exposure target range even when the exposure area is reduced. This distribution may lead to more precise correction of warpage in accordance with the state of warpage.

Thus, in the condition adjustment operation, the area which is irradiated with exposure light (the exposure area) within the exposure target range may be adjusted in accordance with the measured warpage amount. In the condition adjustment operation, the ratio of the number of LEDs 884 (first light sources) that irradiate exposure light to the number of LEDs 884 (second light sources) that do not irradiate exposure light among two of more LEDs 884 (target light sources) that are capable of irradiating exposure light on the exposure target range may be adjusted in accordance with the measurement results of the warpage amount. The controller 100 may perform the obtaining the warpage amount of the wafer W before forming the backside film F and adjusting the processing condition in the exposing operation in accordance with the obtained results of the warpage amount. The controller 100 may store information in advance that associates the warpage amount with the arrangement of LEDs 884 to be lit among the all LEDs 884. The information associating the warpage amount with the arrangement of the LEDs 884 to be lit may be preset by an operator or other personnel.

Returning to FIG. 12, step S06 is executed after step S05. In step S06, for example, the controller 100 controls the transport unit 34 to carry the wafer W from the exposure unit 80 to the heat processing unit 70. The controller 100 then may cause the heat processing unit 70 to apply heat processing to the backside film F after exposure light has been irradiated. This heat processing promotes cross-linking in the portions of the backside film F that have been irradiated with exposure light. The heat processing unit 70 used in step S04 and the heat processing unit 70 used in step S06 may be the same unit or different units. Part of step S06 may correspond to the second heating operation. During performing steps S03 to S06, the wafer W remains with the back surface Wb facing upward (see FIG. 13).

Next, step S07 is executed. In step S07, for example, the controller 100 controls the transport unit 34 to carry the wafer W from the heat processing unit 70 to the reserving unit 50 (second reserving module) provided in the shelf unit 26. The controller 100 then causes the reserving unit 50 to invert the wafer W so that the front surface Wa faces upward and the back surface Wb faces downward. Part of step S07 may correspond to the second reversing operation. The reserving unit 50 used in step S02 and the reserving unit 50 used in step S07 may be the same unit or different units. By executing step S07, the wafer W transitions to a state where the front surface Wa faces upward.

Next, step S08 is executed. In step S08, for example, the controller 100 controls the transport unit 24 to carry the wafer W from the reserving unit 50 to the measurement unit 40. Then, the controller 100, similar to step S01, may acquire image information obtained by imaging the edge surface of the wafer W from the measurement unit 40. Subsequently, the controller 100 may measure the amount of warpage from the image information obtained by the measurement unit 40, in the same manner as in step S01.

The controller 100 may compare between the warpage amount measured in step S01 and the warpage amount measured in step S08 to evaluate whether the series of processes in the substrate processing apparatus 10 has achieved a target correction. Part of step S08 may correspond to the second measuring operation. The measurement unit 40 used in step S01 and the measurement unit 40 used in step S08 may be the same unit or different units.

After executing step S08, the controller 100 may control the transport unit 24 to carry the wafer W from the measurement unit 40 to the cassette C. Thus, the sequence of processing for one wafer W finishes. The controller 100 may similarly execute steps S01 to S08 for each of the other wafers. The period during which the sequence of processing is performed on one wafer W and the period during which the sequence of processing is performed on another wafer W may overlap at least partially.

### Variations

The sequence of processes illustrated in FIG. 12 is merely one example and may be modified as appropriate. In the above sequence of processing, the controller 100 may execute one step and the next step in parallel. The controller 100 may perform some steps in an order different from that described above. The controller 100 may also perform one or more steps having contents different from those described above.

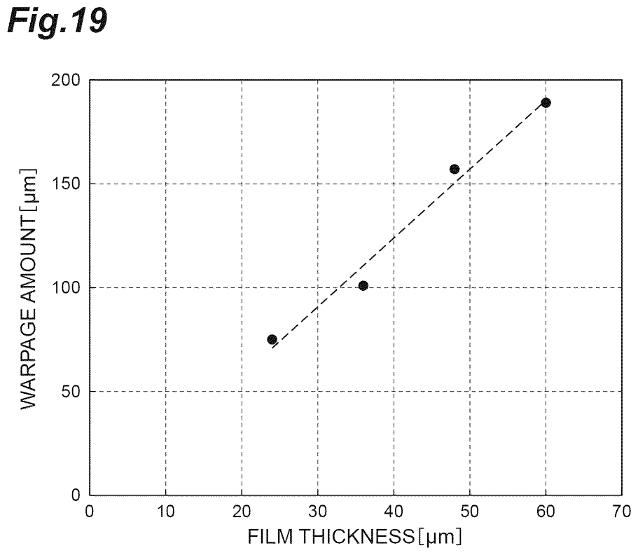

In the condition adjustment operation, instead of adjusting the processing condition in exposing operation, the processing condition in the backside film forming operation may be adjusted. FIG. 19 illustrate measurement results of the warpage amount when the backside film F is formed on the back surface Wb of the wafer W without warpage and then exposing the backside film F, while varying the processing conditions to achieve different film thicknesses. In the graph of FIG. 19, the horizontal axis represents the measured values of film thickness, and the vertical axis represents the measured values of warpage. The four plots in the graph represent the combinations of film thickness and warpage measurements, and the dashed line is a first-order approximation line (approximation line calculated by the least squares method) obtained from the four combinations of measurements.

From the graph in FIG. 19, it is seen that different film thicknesses yield different warpage amounts, indicating a correlation between film thickness and warpage. The controller 100 may adjust the processing condition in the backside film forming operation so that the film thickness increases when the amount of warpage in the wafer W before exposure is relatively large within the same lot. The controller 100 may adjust the processing condition in the backside film forming operation so that the film thickness decreases when the amount of warpage in the wafer W before exposure is relatively small within the same lot.

The controller 100 may adjust the processing condition in the backside film forming operation in accordance with the measurement results of the warpage amount. The controller 100, for example, adjusts a supply amount of the processing liquid L in the liquid processing operation or adjusts a drying time by rotating the wafer W after supplying the processing liquid L in the liquid processing operation. The controller 100 may adjust a heating time or heating temperature in the heating operation in accordance with the measurement results of the warpage amount. The controller 100 may store information in advance that associates the warpage amount with a set value such as the supply amount of the processing liquid L that affects the film thickness. The information associating the warpage amount with the set value such as the supply amount of the processing liquid L that affects the film thickness may be preset by an operator or other personnel.

The controller 100 may adjust the set value of the film thickness based on a comparison between the warpage amount (measured value) of the wafer W before exposure and one or more reference values, in the same manner as adjusting the processing condition of the exposing operation. According to the set value of the film thickness, a set value such as the supply amount of the processing liquid L that affects the film thickness may be determined. The controller 100 may set the film thickness according to the measurement result of the warpage amount by referring to table information in which the warpage amount of the wafer W before exposure and the set value of the film thickness are associated with each other, in the same manner as adjusting the processing condition in the exposing operation.

The controller 100 may generate a linear equation representing the relationship between the warpage amount and the film thickness before producing the wafer W. The controller 100 may set the film thickness according to the measurement result of the warpage amount by using the linear equation representing the relationship between the warpage amount and the film thickness. The linear equation representing the relationship between the warpage amount and the film thickness may be obtained by performing measurements similar to those used to obtain the graph illustrated in FIG. 19. When the film thickness of the backside film F is denoted as “y” and the warpage amount is denoted as “x,” the linear equation may be expressed as “y=ax+b”. In the above linear equation, “a” and “b” represent constants.

The controller 100 may not execute the first measuring operation and the condition adjustment operation. The controller 100 may execute the first measuring operation and the condition adjustment operation, but may not execute the second measuring operation. In at least part of the liquid processing operation, the first heating operation, the exposing operation, and the second heating operation, the wafer W may be supported with the back surface Wb facing downward while the processing is executed. At least one of the first measuring operation and the second measuring operation may be executed using a measurement device provided separately from the substrate processing apparatus 10. In one of the various examples described above, at least a part of the matters described in other examples may be combined.

### Overview of the this Disclosure

This disclosure encompasses the following methods or configurations [1] to and [1A] to [7A].

[1] A substrate processing method, including: performing a backside film forming operation that forms a backside film (F) on a back surface (Wb) of a substrate (W), wherein the substrate (W) includes a front surface (Wa) on which a pattern or device structure (D) is formed, and the back surface (Wb) opposite to the front surface (Wa), and wherein the backside film (F) is configured to generate stress on the back surface (Wb) of the substrate (W) upon exposure; and performing an exposing operation that exposes at least a part of the backside film (F) to reduce warpage of the substrate after the backside film forming operation.

In this substrate processing method, exposure of the backside film (F) generates stress within the film without applying external force to the substrate (W), thereby reducing warpage. For example, warpage is corrected without forming irregularities in the backside film F itself. For example, in a subsequent bonding operation, it is easy for bonding apparatus to hold the back surface (Wb). This method may be useful for facilitating the bonding operation of bonding the substrate (W) to another substrate.

[2] The substrate processing method according to [1], further including: performing a loading operation that carries the substrate (W) into a substrate processing apparatus (10) before the backside film forming operation; and performing an unloading operation that carries the substrate (W) out of the substrate processing apparatus (10) after the exposing operation; wherein the backside film forming operation and the exposing operation are performed in the substrate processing apparatus (10).

In this method, operation to correct warpage is performed by a single substrate processing apparatus, which is useful for simplifying the overall apparatus.

[3] The substrate processing method according to [2], further including: performing a first reversing operation that reverses the substrate (W) such that the back surface (Wb) faces upward before forming the backside film (F); and performing a second reversing operation that reverses the substrate (W) such that the front surface (Wa) faces upward after exposing at least a part of the backside film (F).

In this method, forming the backside film (F) and exposure of the backside film (F) may be performed with the back surface Wb facing upward. It is easy to supply processing liquid and so onto the backside film (F) during the backside film forming operation and the exposing operation.

[4] The substrate processing method according to [3], further including performing a heating operation that heats the substrate (W) after the backside film forming operation, wherein the substrate processing apparatus (10) includes a loading block (20) and a processing block (30) connected to the loading block (20); wherein the loading operation, the unloading operation, the first reversing operation, and the second reversing operation are performed in the loading block (20); and wherein the backside film forming operation, the exposing operation, and the heating operation are performed in the processing block (30).

In this method, within the processing block (30), various processing and transport of the substrate (W) are performed with the back surface (Wb) facing upward. Therefore the variety of support members needed inside the processing block (30) is reduced.

[5] The substrate processing method according to [4], wherein in each of the backside film forming operation, the exposing operation, and the heating operation, the substrate (W) is supported by a supporter (626, 72, 826) so as that the back surface (Wb) faces upward and a region of the front surface (Wa) where the pattern or the device structure (D) is formed does not contact to the supporter (626, 72, 826).

In this method, various processing is executed with the back surface (Wb) facing upward while minimizing impact on the pattern or the device structure (D).

[6] The substrate processing method according to any one of [1] to [5], further including: performing a measuring operation that measures a warpage amount of the substrate (W) before the backside film forming operation; and performing a condition adjustment operation that adjusts a processing condition of at least one of the backside film forming operation and the exposing operation in accordance with the measured warpage amount.

In this method, it is possible to reduce differences in the degree of warpage among substrates (W).

[7] The substrate processing method according to [6], further including performing a second measuring operation that measures the warpage amount of the substrate (W) after the exposing operation and the heating operation.

In this method, while adjusting processing condition in accordance with each substrate (W), it is possible to confirm that the desired warpage correction has been achieved by the backside film forming operation and the exposing operation.

[8] The substrate processing method according to any one of [1] to [7], wherein the backside film (F) is a film whose volume increases or decreases upon the exposure.

[9] The substrate processing method according to any one of [1] to [8], wherein the backside film (F) is a film containing a resin that crosslinks upon the exposure.

[10] The substrate processing method according to [9], wherein forming the backside film (F) includes supplying a processing liquid (L) to the back surface (Wb), wherein the backside film (F) is an expansion film whose volume increases upon the exposure, and wherein the processing liquid (L) is a chemical solution containing a photosensitive epoxy resin or a photosensitive polyimide resin.

[11] The substrate processing method according to one of [1] to [10], wherein the exposing operation includes irradiating exposure light to a predetermined exposure target range which is a part of the backside film (F).

[12] The substrate processing method according to [6] or [7], wherein an exposure target range of the exposing operation is predetermined, and wherein, in the condition adjustment operation, the processing condition of the exposing operation is adjusted such that an irradiation area within the exposure target range varies in accordance with the measured warpage amount, the irradiation area being irradiated with exposure light.

It has been found that by varying the irradiated area within the exposure target range, differences arise in the degree of warpage correction based on forming backside film (F) and exposure of the backside film (F). In this method, warpage correction is tailored to the warpage state of each substrate (W) before processing.

[13] The substrate processing method according to [12], wherein, in the exposing operation, the exposure is performed by irradiating exposure light from at least a part of a plurality of light sources (884) arranged in a first direction (D2); wherein, in the condition adjustment operation, a ratio of a number of first light sources of target light sources to a number of second light sources of the target light sources is adjusted in accordance with the measured warpage amount, the first light sources are configured to emit the exposure light, the second light sources are configured not to emit the exposure light, and the target light sources are two or more light sources of the plurality of light sources (884) and positioned to irradiate the exposure target range with exposure light.

In this method, due to adjusting which of the plurality of light sources (884) emit exposure light, it is easy to vary the exposure area.

[14] The substrate processing method according to [6] or [7], wherein in the condition adjustment operation, the processing condition in the backside film forming operation is adjusted in accordance with the measured warpage amount so that a thickness of the backside film (F) varies.

It has been found that by varying the film thickness of the backside film (F), differences arise in the degree of warpage correction based on forming backside film (F) and exposure of the backside film (F). In this method, warpage correction is tailored to the warpage state of each substrate (W) before processing.

[15] The substrate processing method according to [14], wherein forming the backside film forming operation includes: supplying a processing liquid (L) to the back surface (Wb) and rotating the substrate (W) after supplying the processing liquid (L) so as to dry the back surface (Wb), and wherein, in the condition adjustment operation, at least one of a supply amount of the processing liquid (L) and a drying time by rotation of the substrate (W) is adjusted in accordance with the measured warpage amount.

[16] The substrate processing method according to [14], wherein the backside film forming operation includes: supplying a processing liquid (L) to the back surface (Wb); and heating the substrate (W) after supplying the processing liquid (L), and wherein, in the condition adjustment operation, at least one of a heating time and a heating temperature for the heating the substrate (W) is adjusted in accordance with the measured warpage amount.

[17] The substrate processing method according to any one of [1] to [16], wherein in the exposing operation, exposure of at least a part of the backside film (F) is performed by irradiating exposure light from at least a part of a plurality of light sources (884) arranged in a first direction (D2); and wherein the irradiating exposure light from the at least a part of the plurality of light sources (884) includes irradiating exposure light during at least a part of a period in which the substrate (W) is being rotated.

In this method, it is possible to irradiate exposure light onto specific regions of the backside film (F) set to extend circumferentially around the center of the substrate (W).

[18] The substrate processing method according to any one of [1] to [17], wherein in the exposing operation, exposure of at least a part of the backside film (F) is performed by irradiating exposure light from at least a part of a plurality of light sources (884) arranged in a first direction (D2); and wherein the irradiating exposure light from the at least a part of the plurality of light sources (884) includes irradiating exposure light during at least a part of a period in which the substrate is being moved along a second direction (D1) crossing the first direction (D2).

In this method, it is possible to irradiate exposure light onto specific regions of the backside film (F) set to extend in a single direction along the back surface (Wb).

[19] A non-transitory computer-readable storage medium storing a program for causing an apparatus to execute the method according to any one of [1] to [18].

This program executes the substrate processing method of [1]. Therefore, this program may be useful for facilitating the bonding operation of bonding the substrate (W) to another substrate.

[1A] A substrate processing apparatus (10), including: a film forming module (60,70) configured to form a backside film (F) on a back surface (Wb) of a substrate (W), wherein the substrate (W) includes a front surface (Wa) on which a pattern or device structure (D) is formed and the back surface (Wb) opposite to the front surface (Wa), and wherein the backside film (F) is configured to generate stress on the back surface (Wb) of the substrate upon exposure; and an exposing module (80) configured to expose at least a part of the backside film (F) to reduce warpage of the substrate (W) after forming the backside film (F).

This apparatus (10) may be useful for facilitating the bonding operation of bonding the substrate (W) to another substrate in the same manner as the method of [1].

[2A] The substrate processing apparatus (10) according to [1A], further including a loading block (20) configured to: carry the substrate (W) without the backside film (F) into the substrate processing apparatus (10); and carry the substrate (W) processed by the film forming module (60, 70) and the exposing module (80) out of the substrate processing apparatus (10).

In this apparatus, it is useful for simplifying the overall apparatus in the same manner as the method of [2].

[3A] The substrate processing apparatus (10) according to [2A], further including: a first reserving module (50) configured to reserve the substrate (W) without the backside film (F) such that the back surface (Wb) faces upward; and a second reserving module (50) configured to reserve the substrate (W) with at least a part of the backside film (F) exposed such that the front surface (Wa) faces upward.

In this apparatus, it is easy to supply processing liquid and so on to the backside film (F) during the forming the backside film (F) and exposing the backside film (F) in the same manner as the method of [3].

[4A] The substrate processing apparatus (10) according to [3A], wherein the first reserving module (50) and the second reserving module (50) are disposed in the loading block (20), and the apparatus (10) further includes a processing block (30) connected to the loading block (20), the processing block (30) being configured to house the film forming module (60, 70), a heat processing module (70) configured to heat the backside film (F), and the exposing module (80).

In this apparatus, the variety of support members needed inside the processing block (30) is reduced in the same manner as the method of [4].

[5A] The substrate processing apparatus (10) according to [4A], wherein each of the film forming module (60, 70), the heat processing module (70), and the exposing module (80) includes a supporter (626, 72, 826) configured to support the substrate (W) with the back surface (Wb) facing upward so as not to contact a region of the front surface (Wa) where the pattern or device structure (D) is formed.

In this apparatus, various processing are executed with the back surface (Wb) facing upward while minimizing impact on the pattern or the device structure (D) in the same manner as the method of [5].

[6A] The substrate processing apparatus (10) according to any one of [1A] to [5A], further including a controller (100) configured to: obtain a warpage amount of the substrate (W) before the film forming module (60, 70) forms the backside film (F); and adjust a processing condition of at least one of the film forming module (60, 70) and the exposing module (80) in accordance with the obtained warpage amount.

In this apparatus, it is possible to reduce differences in the degree of warpage among substrates (W) in the same manner as the method of [6].

[7A] The substrate processing apparatus (10) according to any one of [1A] to [6A], wherein the exposing module (80) includes: a rotation holder (82) configured to hold and rotate the substrate (W); a plurality of light sources (884) arranged in a first direction (D2) and configured to emit exposure light; and a driver (85) configured to move the rotation holder (884) along a second direction (D1) crossing the first direction (D2) so that, in plan view, the substrate (W) crosses the plurality of light sources (884).

In this apparatus, it is possible to irradiate exposure light onto at least one of specific regions of the backside film (F) set to extend circumferentially around the center of the substrate (W), and specific regions of the backside film (F) set to extend in a single direction along the back surface (Wb)

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A substrate processing method, comprising:
performing a backside film forming operation that forms a backside film on a back surface of a substrate, wherein the substrate comprises a front surface on which a pattern or device structure is formed and the back surface opposite to the front surface, and wherein the backside film is configured to generate stress on the back surface of the substrate upon exposure; and
performing an exposing operation that exposes at least a part of the backside film to reduce warpage of the substrate after the backside film forming operation.

2. The substrate processing method according to claim 1, further comprising:
performing a loading operation that carries the substrate into a substrate processing apparatus before the backside film forming operation; and
performing an unloading operation that carries the substrate out of the substrate processing apparatus after the exposing operation;
wherein the backside film forming operation and the exposing operation are performed in the substrate processing apparatus.

3. The substrate processing method according to claim 2, further comprising:
performing a first reversing operation that reverses the substrate such that the back surface faces upward before the backside film forming operation; and
performing a second reversing operation that reverses the substrate such that the front surface faces upward after the exposing operation.

4. The substrate processing method according to claim 3, further comprising performing a heating operation that heats the substrate after forming the backside film,
wherein the substrate processing apparatus comprises a loading block and a processing block connected to the loading block;
the loading operation, the unloading operation, the first reversing operation, and the second reversing operation are performed in the loading block; and
the film forming operation, the exposing operation, and the heating operation are performed in the processing block.

5. The substrate processing method according to claim 4,
wherein in each of the backside film forming operation, the exposing operation, and the heating operation, the substrate is supported by a supporter so as that the back surface faces upward and a region of the front surface where the pattern or the device structure is formed does not contact to the supporter.

6. The substrate processing method according to claim 1, further comprising:
performing a measuring operation that measures a warpage amount of the substrate before the backside film forming operation; and
performing a condition adjustment operation that adjusts a processing condition of at least one of the backside film forming operation and the exposing operation in accordance with the measured warpage amount.

7. The substrate processing method according to claim 6, further comprising performing a second measuring operation that measures the warpage amount of the substrate after the exposing operation and heating operation.

8. The substrate processing method according to claim 1, wherein the backside film is a film whose volume increases or decreases upon the exposure.

9. The substrate processing method according to claim 1, wherein the backside film is a film containing a resin that crosslinks upon the exposure.

10. The substrate processing method according to claim 9,
wherein the backside film forming operation includes supplying a processing liquid to the back surface,
wherein the backside film is an expansion film whose volume increases upon the exposure, and
wherein the processing liquid is a chemical solution containing a photosensitive epoxy resin or a photosensitive polyimide resin.

11. The substrate processing method according to claim 1, wherein the exposing operation includes irradiating exposure light to a predetermined exposure target range which is a part of the backside film.

12. The substrate processing method according to claim 6,
wherein an exposure target range of the exposing operation is predetermined, and
wherein, in the condition adjustment operation, the processing condition of the exposing operation is adjusted such that an irradiation area within the exposure target range varies in accordance with the measured warpage amount.

13. The substrate processing method according to claim 12,
wherein, in the exposing operation, the exposure is performed by irradiating exposure light from at least a part of a plurality of light sources arranged in a first direction; and
wherein, in the condition adjustment operation, a ratio of a number of first light sources of target light sources to a number of second light sources of the target light sources is adjusted in accordance with the measured warpage amount, wherein the first light sources are configured to emit the exposure light and, the second light sources are configured not to emit the exposure light, and wherein the target light sources are two or more light sources of the plurality of light sources and positioned to irradiate the exposure target range.

14. The substrate processing method according to claim 6,
wherein, in the condition adjustment operation, the processing condition of the backside film forming operation is adjusted in accordance with the measured warpage amount so that a thickness of the backside film varies.

15. The substrate processing method according to claim 14,
wherein the backside film forming operation comprises:
supplying a processing liquid to the back surface; and
rotating the substrate after supplying the processing liquid so as to dry the back surface, and
wherein, in the condition adjustment operation, at least one of a supply amount of the processing liquid and a drying time by rotation of the substrate is adjusted in accordance with the measured warpage amount.

16. The substrate processing method according to claim 14,
wherein the backside film forming operation comprises:
supplying a processing liquid to the back surface; and
heating the substrate after supplying the processing liquid, and
wherein in the condition adjustment operation, at least one of a heating time and a heating temperature for the heating the substrate is adjusted in accordance with the measured warpage amount.

17. The substrate processing method according to claim 1,
wherein, in the exposing operation, the exposure is performed by irradiating exposure light from at least a part of a plurality of light sources arranged in a first direction; and
wherein the irradiating exposure light from the at least a part of the plurality of light sources includes irradiating exposure light during at least a part of a period in which the substrate is being rotated.

18. The substrate processing method according to claim 1,
wherein in the exposing operation, the exposure is performed by irradiating exposure light from at least a part of a plurality of light sources arranged in a first direction; and
wherein the irradiating exposure light from the at least a part of the plurality of light sources includes irradiating exposure light during at least a part of a period in which the substrate is being moved along a second direction crossing the first direction.

19. A non-transitory computer-readable storage medium storing a program for causing an apparatus to execute the method according to claim 1.

20. A substrate processing apparatus, comprising:
a film forming module configured to form a backside film on a back surface of a substrate, wherein the substrate comprises a front surface on which a pattern or device structure is formed and the back surface opposite to the front surface, and wherein the backside film is configured to generate stress on the back surface of the substrate upon exposure; and
an exposing module configured to expose at least a part of the backside film to reduce warpage of the substrate after forming the backside film.
